(19) United States
(12) Patent Application Publication
(10) Pub. No.: US 2025/0340990 A1
(43) Pub. Date: Nov. 6, 2025

(54) SUBSTRATE PROCESSING APPARATUS

(71) Applicant: HANWHA SOLUTIONS CORPORATION, Seoul (KR)

(72) Inventors: No Won KWAK, Seoul (KR); Seon Ki MIN, Seoul (KR)

(73) Assignee: HANWHA SOLUTIONS CORPORATION, Seoul (KR)

(21) Appl. No.: 19/198,350

(22) Filed: May 5, 2025

(30) Foreign Application Priority Data
May 3, 2024 (KR) 10-2024-0059202

(51) Int. Cl. C23C 16/52; C23C 16/44; C23C 16/455; C23C 16/458; H10K 30/50

(52) U.S. Cl. CPC C23C 16/52; C23C 16/4412; C23C 16/45544; C23C 16/4583; H10K 30/50

(57) ABSTRACT

A substrate processing apparatus includes a process chamber configured to provide a processing space for processing a substrate, a gas injector configured to inject a process gas onto the substrate, an exhaust line configured to provide a gas transfer path for discharging process by-products remaining in the process chamber, an auxiliary line connected to the exhaust line and configured to provide a gas transfer path for injecting a pressure regulating gas into the exhaust line, and a processor configured to regulate injection of the pressure regulating gas, wherein the processor allows the pressure regulating gas to be injected into the exhaust line during a pressure regulating section of a process cycle for the substrate.

### CROSS-REFERENCE TO RELATED APPLICATION

This application claims priority to and the benefit of Korean Patent Application No. 10-2024-0059202, filed on May 3, 2024, the disclosure of which is incorporated herein by reference in its entirety.

### BACKGROUND

### 1. Field of the Invention

The present disclosure relates to a substrate processing apparatus, and more particularly, to a substrate processing apparatus capable of regulating an internal pressure of a process chamber by injecting a pressure regulating gas into an exhaust line while injecting a process gas into the process chamber.

### 2. Discussion of Related Art

Atomic layer deposition (ALD) or the like may be used for surface treatment of a substrate that is used as a material for a solar cell. In the case of ALD, a source gas undergoes a chemical reaction on the surface of the substrate and forms a thin film. In particular, in the case of ALD, a thin film with a thickness similar to the diameter of an atom can be formed because the thin film is formed by a single layer of a raw material gas adhering to the surface of the substrate.

In the case of ALD, a thin film is formed at the atomic layer level, which provides the advantage of excellent thin film quality, but a deposition process takes a relatively long time, which has the disadvantage of low productivity. In order to compensate for such low productivity, a plurality of substrates may be inserted into a single process chamber, and the thin-film deposition process may be performed on the plurality of substrates.

Meanwhile, thin film deposition may be performed as a process gas flowing inside the process chamber comes into contact with the surfaces of the substrates, but opportunities for contact with the process gas may not be uniformly provided across different substrates. In such a case, the quality of the thin film formed on each substrate may vary.

Accordingly, there is a need for an invention that ensures uniform contact opportunities with a process gas for each of a plurality of substrates accommodated in a process chamber.

### Prior Art Document

Korean Registered Patent Publication No. 10-1219381 (Jan. 21, 2013)

### SUMMARY OF THE INVENTION

The present disclosure is directed to providing a substrate processing apparatus capable of regulating an internal pressure of a process chamber by injecting a pressure regulating gas into an exhaust line while injecting a process gas into the process chamber.

It should be noted that objects of the present disclosure are not limited to the above-described object, and other objects of the present disclosure will be apparent to those skilled in the art from the following descriptions.

According to an aspect of the present disclosure, there is provided a substrate processing apparatus including a process chamber configured to provide a processing space for processing a substrate, a gas injector configured to inject a process gas onto the substrate, an exhaust line configured to provide a gas transfer path for discharging process by-products remaining in the process chamber, an auxiliary line connected to the exhaust line and configured to provide a gas transfer path for injecting a pressure regulating gas into the exhaust line, and a processor configured to regulate injection of the pressure regulating gas, wherein the processor allows the pressure regulating gas to be injected into the exhaust line during a pressure regulating section of a process cycle for the substrate.

The pressure regulating section may include a section in which a source gas is injected onto the substrate.

The source gas may be a gas containing at least one metal element selected from tin (Sn), nickel (Ni), copper (Cu), titanium (Ti), tungsten (W), gold (Au), silver (Ag), iron (Fe), magnesium (Mg), zirconium (Zr), and platinum (Pt), or a gas containing at least one selected from trimethylaluminum (TMA), diethylene glycol (DEG), titanium chloride (TiCl), tetrakis-dimethylamino tin (TDMASn), methylcyclopentadienyl nickel (MeCpNi), ethylcyclopentadienyl nickel (EtCpNi), and diethyl zinc (DEZ).

The pressure regulating gas may include at least one of nitrogen (N₂) or argon (Ar).

The processor may allow a preset amount of the pressure regulating gas to be injected into the exhaust line for each pressure regulating section of a plurality of process cycles for the substrate.

The processor may divide the pressure regulating section into a plurality of sub-sections and allow a preset amount of the pressure regulating gas to be injected into the exhaust line for each sub-section.

The processor may allow the amount of the pressure regulating gas injected into the exhaust line to decrease as the plurality of sub-sections proceed.

The processor may prevent the pressure regulating gas from being injected into the exhaust line in a last sub-section among the plurality of sub-sections.

The substrate processing apparatus may further include a gas regulator provided in the auxiliary line and configured to regulate a transfer amount of the pressure regulating gas transferred through the auxiliary line.

The substrate processing apparatus may further include an auxiliary valve provided in the auxiliary line and configured to open or close the auxiliary line.

The substrate may be used as a material for a solar cell using a perovskite material.

The process chamber may include a substrate inlet/outlet formed on one side of the process chamber; and a shutter configured to open or close the substrate inlet/outlet.

The process chamber may further include an exhaust port connected to the exhaust line, and the exhaust port may be disposed on a side of the process chamber opposite to a side of the process chamber on which the gas injector is disposed.

The substrate processing apparatus may further include a substrate support part configured to support the substrate while the substrate is brought into or taken out of the process chamber.

The substrate support part may include a main support part provided in the form of a panel; and a plurality of sub-support parts arranged in a longitudinal direction of the main support part.

Specific details of the embodiments are included in the detailed description and drawings.

### BRIEF DESCRIPTION OF THE DRAWINGS

The above and other objects, features, and advantages of the present disclosure will become more apparent to those of ordinary skill in the art by describing exemplary embodiments thereof in detail with reference to the accompanying drawings, in which:

FIG. 1 is a diagram illustrating a substrate processing apparatus according to an embodiment of the present disclosure;

FIG. 2 is a diagram illustrating a state in which substrates are accommodated in a process chamber;

FIG. 3 is a diagram for describing process cycles;

FIG. 4 is a diagram for describing that a preset amount of a pressure regulating gas is injected for each pressure regulating section;

FIG. 5 is a diagram for describing the division of a pressure regulating section into a plurality of sub-sections;

FIG. 6 is a diagram for describing that no pressure regulating gas is injected in the last sub-section among the plurality of sub-sections; and

FIG. 7 is a diagram for describing that an amount of a pressure regulating gas decreases as the plurality of sub-sections progress.

### DETAILED DESCRIPTION OF EXEMPLARY EMBODIMENTS

Hereinafter, exemplary embodiments of the present disclosure will be described in detail with reference to the accompanying drawings. Advantages and features of the present disclosure and implementation methods thereof will be clarified through the following embodiments described with reference to the accompanying drawings. However, the present disclosure is not limited to the embodiments described below and may be implemented with a variety of different forms. The embodiments are merely provided to allow those skilled in the art to completely understand the scope of the present disclosure, and the present disclosure is defined only by the scope of the claims. Throughout the specification, like reference numerals refer to like elements.

Unless otherwise defined, all terms (including technical and scientific terms) used in the present specification may be used in a sense commonly understood by those skilled in the art to which the present specification pertains. In addition, it will be understood that terms, such as those defined in commonly used dictionaries, will not be interpreted in an idealized or overly formal sense unless expressly so defined herein.

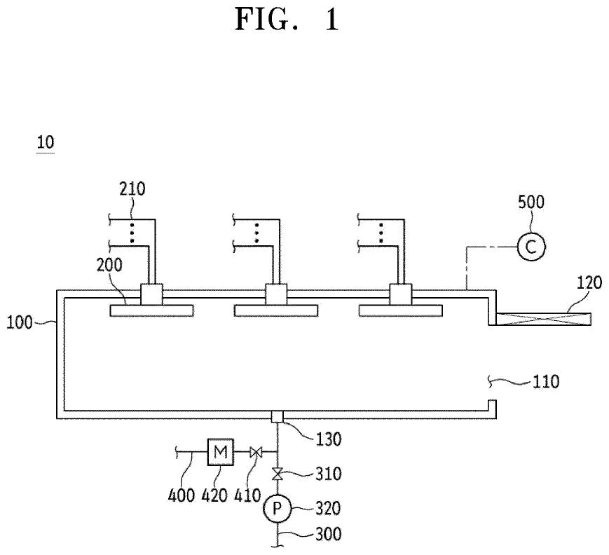

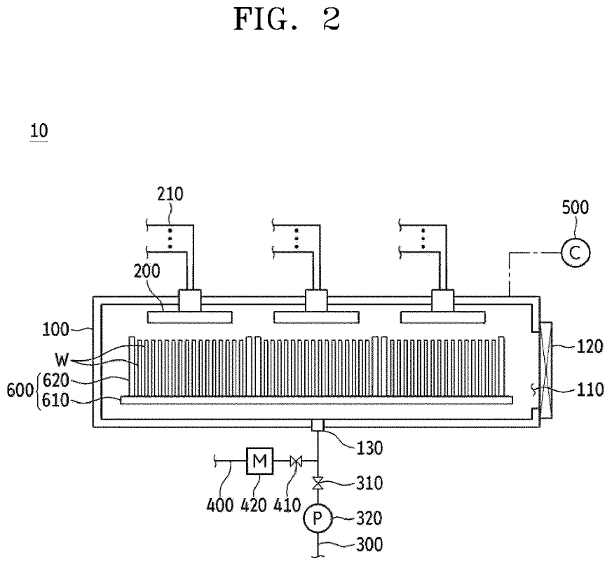

FIG. 1 is a diagram illustrating a substrate processing apparatus according to an embodiment of the present disclosure, and FIG. 2 is a diagram illustrating a state in which substrates are accommodated in a process chamber.

Referring to FIGS. 1 and 2, a substrate processing apparatus 10 according to an embodiment of the present disclosure includes a process chamber 100, a gas injector 200, an exhaust line 300, an auxiliary line 400, and a processor 500.

The substrate processing apparatus 10 according to the embodiment of the present disclosure may deposit a thin film on a substrate W. For example, the substrate processing apparatus 10 may deposit a thin film on the substrate W using atomic layer deposition (ALD). Alternatively, the substrate processing apparatus 10 may also deposit a thin film on the substrate W using chemical vapor deposition (CVD), plasma enhanced chemical vapor deposition (PECVD), or plasma enhanced atomic layer deposition (PEALD).

In the present disclosure, the substrate W may be used as a material for a solar cell. For example, the substrate W may correspond to a cell of the solar cell. In addition, in the present disclosure, the substrate W may be used as a material for a solar cell using a perovskite material. Accordingly, a process for the substrate W, which will be described below, may include depositing a thin film of a material having a perovskite structure on a surface of the substrate W as a light-absorbing layer.

The process chamber 100 may provide a processing space for processing the substrate W. The process chamber 100 may provide an accommodation space for various components required for processing the substrate W.

A substrate inlet/outlet 110 may be formed on one side of the process chamber 100 to allow the entry and exit of the substrate W. The substrate W may be brought into the process chamber 100 or taken out of the process chamber 100 through the substrate inlet/outlet 110.

A shutter 120 may be provided in the process chamber 100. The shutter 120 may open or close the substrate inlet/outlet 110. When the shutter 120 opens the substrate inlet/outlet 110, the substrate W may be brought into or taken out of the process chamber 100 through the substrate inlet/outlet 110. When a process is performed on the substrate W, the shutter 120 may close the substrate inlet/outlet 110 to isolate the interior of the process chamber 100 from the outside.

FIG. 2 illustrates a state in which the substrate W is brought into the process chamber 100. The substrate W may be brought into or taken out of the process chamber 100 while being supported by a substrate support part 600.

The substrate support part 600 may include a main support part 610 and a sub-support part 620. The main support part 610 may be provided in the form of a panel and may support the sub-support part 620. The sub-support part 620 may be supported by the main support part 610 and may move integrally with the main support part 610. A plurality of sub-support parts 620 may be disposed on the main support part 610. The sub-support parts 620 may support the substrate W. Specifically, the sub-support parts 620 may support a plurality of substrates W. The plurality of substrates W may be loaded onto the sub-support parts 620 in the same posture.

The substrates W may be loaded on the sub-support parts 620 to align with a flow direction of a gas flowing inside the process chamber 100. For example, the substrates W may be arranged parallel to the ground and loaded in a plurality of layers on the sub-support parts 620, or may be arranged perpendicular to the ground such that the plurality of substrates are arranged side by side in a horizontal direction. Alternatively, the plurality of substrates W may be arranged side by side on the sub-support parts 620 while inclined at a certain angle with respect to the ground or the gas flow direction.

The plurality of sub-support parts 620 may be provided. The plurality of sub-support parts 620 may be arranged side by side in a longitudinal direction of the main support part 610 and may be fixed to the main support part 610. A process may be performed simultaneously on the plurality of substrates W accommodated in the process chamber 100. That is, a thin-film deposition process may be performed simultaneously on the plurality of substrates W.

The gas injector 200 serves to inject a process gas onto the substrates W. The gas injector 200 may diffuse and inject the process gas. The process gas diffused inside the process chamber 100 may react with the surfaces of the substrates W, thereby forming thin films on the substrates W.

The gas injector 200 may include at least one gas nozzle (not shown) or gas hole (not shown) disposed in a certain pattern on an injection surface thereof to inject a process gas toward the substrate support part 600. The shape and arrangement position of the gas injector 200 may be determined in consideration of a height at which the substrates W are disposed, gaps between the adjacent substrates W, and a distribution area of the substrates W, so that the gas can be uniformly injected onto all the substrates W.

In the present disclosure, the process gas may include a source gas, a source purge gas, a reaction gas, and a reaction purge gas. The source gas, the source purge gas, the reaction gas, and the reaction purge gas may be sequentially injected from the gas injector 200, or at least some thereof may be injected simultaneously. The source gas and the reaction gas may collide and react with each other after being injected from the gas injector 200. In addition, the source gas activated by the reaction gas may come into contact with the substrate W, thereby allowing a process to be performed on the substrate W. For example, the activated source gas may be deposited as a thin film on the substrate W.

A gas transfer line 210 may be connected to the gas injector 200. A plurality of gas transfer lines 210 may be provided, and the plurality of gas transfer lines 210 may provide transfer paths for different process gases. For example, the plurality of gas transfer lines 210 may provide transfer paths for each of the source gas, the source purge gas, the reaction gas, and the reaction purge gas.

The process chamber 100 may include an exhaust port 130. The exhaust port 130 may be provided on a side of the process chamber 100 opposite to one side of the process chamber 100 on which the gas injector 200 is provided. For example, when the gas injector 200 is disposed on an upper portion of the process chamber 100, the exhaust port 130 may be disposed on a lower portion of the process chamber 100, and when the gas injector 200 is disposed on the left side of the process chamber 100, the exhaust port 130 may be disposed on the right side of the process chamber 100. Meanwhile, providing the exhaust port 130 on the side of the process chamber 100 opposite to one side of the process chamber 100 on which the gas injector 200 is provided is merely an example, and according to some embodiments of the present disclosure, the positions of the gas injector 200 and the exhaust port 130 may be determined in various ways in consideration of the process efficiency and exhaust efficiency for the substrates W.

The exhaust port 130 may provide a discharge path for process by-products. Here, the process by-products may include all substances to be discharged from the process chamber 100, such as remaining gases that were supplied to the process chamber 100 but were not used for thin film formation. For example, the process by-products may include the source gas, the reaction gas, the source purge gas, and the reaction purge gas.

At least one exhaust port 130 may be disposed in the process chamber 100. For example, as shown in FIGS. 1 and 2, the exhaust port 130 may be disposed at a point facing the gas injector 200 disposed in the center among a plurality of gas injectors 200 disposed inside the process chamber 100. Further, according to some embodiments of the present disclosure, a plurality of exhaust ports 130 may be provided. In this case, the plurality of exhaust ports 130 may be disposed at points corresponding to the plurality of gas injectors 200. The exhaust port 130 may include at least one discharge hole (not shown). The process by-products introduced into the discharge hole may move into the exhaust line 300 to be discharged.

The exhaust line 300 may be connected to the exhaust port 130. The exhaust line 300 may provide a gas transfer path for discharging process by-products remaining inside the process chamber 100. To this end, the exhaust line 300 may provide a transfer path for the process by-products introduced through the exhaust port 130.

An exhaust pump 320 may be provided in the exhaust line 300. The exhaust pump 320 may pressurize an inner space of the exhaust line 300 so that the process by-products introduced through the exhaust port 130 are transferred through the exhaust line 300. The process by-products transferred through the exhaust line 300 may be discharged from the process chamber 100.

An exhaust valve 310 may be provided in the exhaust line 300. The exhaust valve 310 may open or close the exhaust line 300. When the exhaust valve 310 opens the exhaust line 300, process by-products may be transferred through the exhaust line 300. When the exhaust valve 310 closes the exhaust line 300, the transfer of process by-products through the exhaust line 300 may be blocked.

The auxiliary line 400 may be connected to the exhaust line 300, and may provide a gas transfer path for injecting a pressure regulating gas into the exhaust line 300. In the present disclosure, the pressure regulating gas may be used to adjust an internal pressure of the process chamber 100. Specifically, the pressure regulating gas may increase the internal pressure of the process chamber 100. When the pressure regulating gas is injected into the exhaust line 300 through the auxiliary line 400, the transfer of process by-products through the exhaust line 300 may be delayed, which may result in an increase in the internal pressure of the process chamber 100.

As described above, in the present disclosure, the thin film deposited on the surface of the substrate W may include a material having a perovskite structure. The source gas used for depositing a thin film of such a material may be a gas containing at least one metal element selected from tin (Sn), nickel (Ni), copper (Cu), titanium (Ti), tungsten (W), gold (Au), silver (Ag), iron (Fe), magnesium (Mg), zirconium (Zr), and platinum (Pt). Alternatively, the source gas may be a gas containing at least one selected from trimethylaluminum (TMA), diethylene glycol (DEG), titanium tetrachloride (TiCl), tetrakis(dimethylamino)tin (TDMASn), methylcyclopentadienyl nickel (MeCpNi), ethylcyclopentadienyl nickel (EtCpNi), and diethyl zinc (DEZ). Such a source gas may be relatively less volatile than gases typically used for thin film formation of common materials. When a thin film is deposited using an improperly vaporized source gas, the quality of the thin film may degrade.

When the pressure regulating gas is injected into the exhaust line 300 through the auxiliary line 400, the internal pressure of the process chamber 100 increases, and a residence time of the source gas inside the process chamber 100 may increase. In this case, opportunities for contact between the source gas and the substrate W and a reaction time may increase, thereby improving the quality of the thin film deposited on the substrate W. In particular, as the reaction between the source gas and the substrate W is efficiently performed not only on the substrate W or substrate area adjacent to the gas injector 200 but also on the substrate W or substrate area relatively far from the gas injector 200, a reduction in the thickness of the thin film in the corresponding substrate W or substrate area may be prevented.

In the present disclosure, the pressure regulating gas may include at least one of nitrogen (N₂) and argon (Ar). Alternatively, the pressure regulating gas may include at least one of the source purge gas and the reaction purge gas.

A gas regulator 420 may be provided in the auxiliary line 400. The gas regulator 420 may regulate a transfer amount of the pressure regulating gas transferred through the auxiliary line 400. For example, a mass flow controller (MFC) may perform the role of the gas regulator 420. The amount of pressure regulating gas injected into the exhaust line 300 through the auxiliary line 400 may be regulated by the gas regulator 420.

An auxiliary valve 410 may be provided in the auxiliary line 400. The auxiliary valve 410 may open or close the auxiliary line 400. When the auxiliary valve 410 opens the auxiliary line 400, the pressure regulating gas may be transferred through the auxiliary line 400. When the auxiliary valve 410 closes the auxiliary line 400, the transfer of the pressure regulating gas through the auxiliary line 400 may be blocked.

The processor 500 may perform overall control of the substrate processing apparatus 10. For example, the processor 500 may operate the shutter 120 to open and close the substrate inlet/outlet 110. In addition, the processor 500 may control a separate driving part (not shown) to allow the substrate support part 600 to be brought into or taken out of the process chamber 100.

Further, the processor 500 may control the process for the substrate W. For example, the processor 500 may regulate the injection of the pressure regulating gas. At this time, the processor 500 may allow the pressure regulating gas to be injected into the exhaust line 300 during a pressure regulating section of a process cycle for the substrate W. The processor 500 may prevent the injection of the pressure regulating gas in sections in which the injection of the pressure regulating gas is not needed and allow the injection of the pressure regulating gas only in sections in which the injection of the pressure regulating gas is required.

The processor 500 may include an electronic control unit (ECU), a central processing unit (CPU), a processor, or a system on chip (SoC). The processor 500 may drive an operating system or an application to control a plurality of hardware or software components and may perform various data processing and calculation operations. The processor 500 may be configured to execute at least one command stored in a memory and store the result data of execution in the memory.

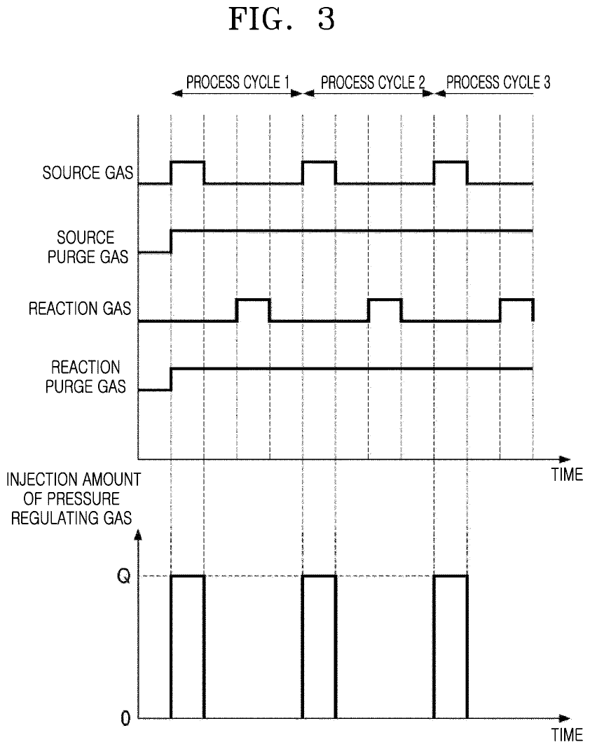

Hereinafter, the regulation of the injection of the pressure regulating gas by the processor 500 will be described with reference to FIGS. 3 to 7.

FIG. 3 is a diagram for describing process cycles.

Referring to FIG. 3, a plurality of processes may be sequentially performed to deposit a thin film 900 on the substrate W.

In order to deposit the thin film 900 on the substrate W, the source gas may be injected into the process chamber 100. The source purge gas may be continuously supplied during the process for the substrate W to pressurize the source gas. The source gas may be injected onto the surface of the substrate W through the gas injector 200. A portion of the source gas injected onto the substrate W is adsorbed onto the surface of the substrate W, while another portion thereof may not be adsorbed. The non-adsorbed source gas may be layered on the adsorbed source gas or remain suspended inside the process chamber 100.

After the source gas is injected onto the substrate W, the source gas may be purged from the process chamber 100. An operation in which the source gas is purged from the process chamber 100 may include an operation in which the source gas that is not adsorbed onto the surface of the substrate W is discharged from the process chamber 100. That is, when the source gas is purged from the process chamber 100, only the source gas adsorbed onto the substrate W remains, and the source gas that is layered on the adsorbed source gas or floating in the process chamber 100 may be discharged to the outside of the process chamber 100. Thus, a single source gas layer may be formed on the surface of the substrate W.

After the source gas is purged, the reaction gas may be injected into the process chamber 100. The reaction purge gas may be continuously supplied during the process for the substrate W to pressurize the reaction gas. The reaction gas may be injected onto the surface of the substrate W through the gas injector 200. The reaction gas may react with the source gas adsorbed on the substrate W to form the thin film 900.

A single process cycle is formed as the source gas and the reaction gas are supplied to the process chamber 100 to form the thin film 900, and a plurality of thin films 900 may be deposited on the substrate W through a plurality of process cycles.

The processor 500 may allow the pressure regulating gas to be injected into the exhaust line 300 during a pressure regulating section of the process cycle for the substrate W. To this end, the processor 500 may control the auxiliary valve 410. The processor 500 may control the auxiliary valve 410 to open the auxiliary line 400 in the pressure regulating section, and control the auxiliary valve 410 to close the auxiliary line 400 in sections other than the pressure regulating section.

The pressure regulating section may include a section in which the source gas is injected onto the substrate W. As described above, the source gas may be a gas that is not relatively easily vaporized. As the pressure regulating gas is injected into the exhaust line 300 in the section in which the source gas is injected, the internal pressure of the process chamber 100 in the corresponding section increases, thereby improving the reaction efficiency between the source gas and the substrate W.

The processor 500 may control the pressure regulating gas to be injected into the exhaust line 300 for a first period of time. Here, the first period of time may be a time during which the source gas is injected onto the substrate W in the process cycle. The processor 500 may regulate a flow rate of the source gas included in the process chamber 100 and improve the reaction efficiency between the source gas and the substrate W by increasing the internal pressure of the process chamber 100 for the first period of time. In particular, as the pressure regulating gas is injected into the exhaust line 300, the material intended to be adsorbed or deposited may be formed with a uniform thickness even on the substrate W located at a relatively greater distance from the gas injector 200. Accordingly, the issue of thickness reduction caused by insufficient adsorption on the substrate W located at a relatively greater distance from the gas injector 200 may be mitigated, and improved uniformity characteristics may be achieved.

Further, the processor 500 may control the injection of the pressure regulating gas to prevent the pressure regulating gas from being injected into the exhaust line 300 after the first period of time has elapsed. Accordingly, in the operation in which the source gas is purged after the operation in which the source gas is injected onto the substrate W, the internal pressure of the process chamber 100 decreases, and the flow rate increases, thereby allowing the gas remaining inside the process chamber 100 to be rapidly discharged.

The processor 500 may allow the same amount of the pressure regulating gas to be injected into the exhaust line 300 during each of a plurality of pressure regulating sections included in the plurality of process cycles. For example, when a preset amount of the pressure regulating gas is Q, the amount Q of the pressure regulating gas may be injected into the exhaust line 300 in every pressure regulating section. The amount of the pressure regulating gas injected into the exhaust line 300 may be regulated by the gas regulator 420. The processor 500 may regulate the amount of the pressure regulating gas injected into the exhaust line 300 by controlling the gas regulator 420.

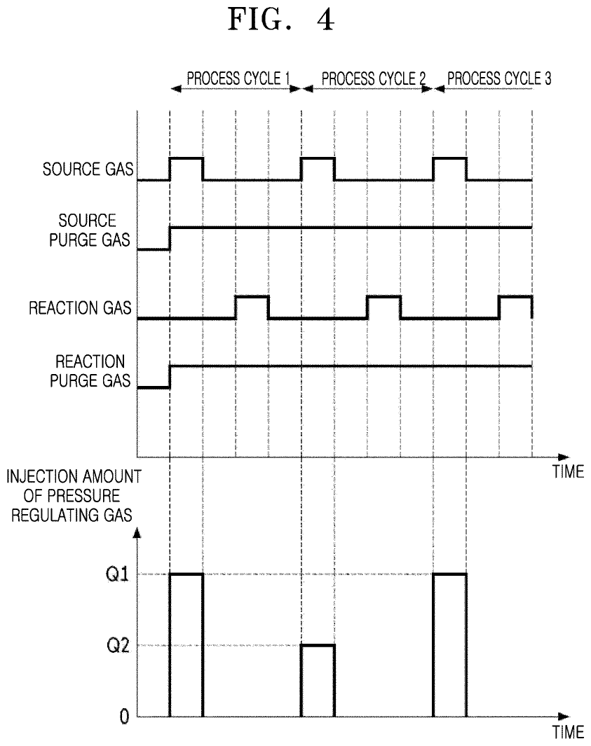

FIG. 4 is a diagram for describing that a preset amount of a pressure regulating gas is injected for each pressure regulating section.

Referring to FIG. 4, the processor 500 may allow a preset amount of a pressure regulating gas to be injected into the exhaust line 300 for each pressure regulating section of the plurality of process cycles for the substrate W.

For example, the processor 500 may allow an amount Q1 of the pressure regulating gas to be injected during the first period of time in the pressure regulating section of process cycle 1, an amount Q2 of the pressure regulating gas to be injected during the first period of time in the pressure regulating section of process cycle 2, and an amount Q3 of the pressure regulating gas to be injected during the first period of time in the pressure regulating section of process cycle 3. Here, Q1, Q2, and Q3 may all be different, or some thereof may be the same. FIG. 4 illustrates that the amount Q1 of the pressure regulating gas is injected during the first period of time in the pressure regulating section of process cycle 1 and process cycle 3, while the amount Q2 of the pressure regulating gas is injected during the first period of time in the pressure regulating section of process cycle 2. For example, the processor 500 may regulate the injection of the pressure regulating gas so that the amount of the injected pressure regulating gas alternates between Q1 and Q2 as the process cycles proceed.

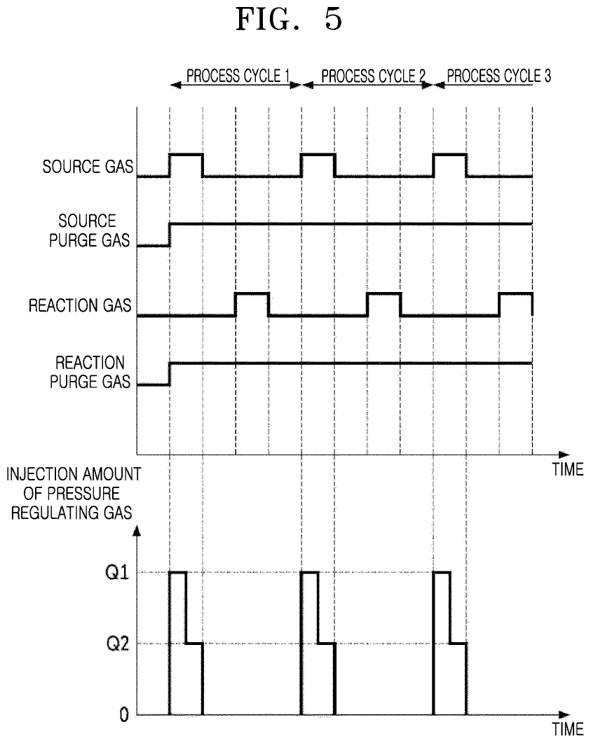

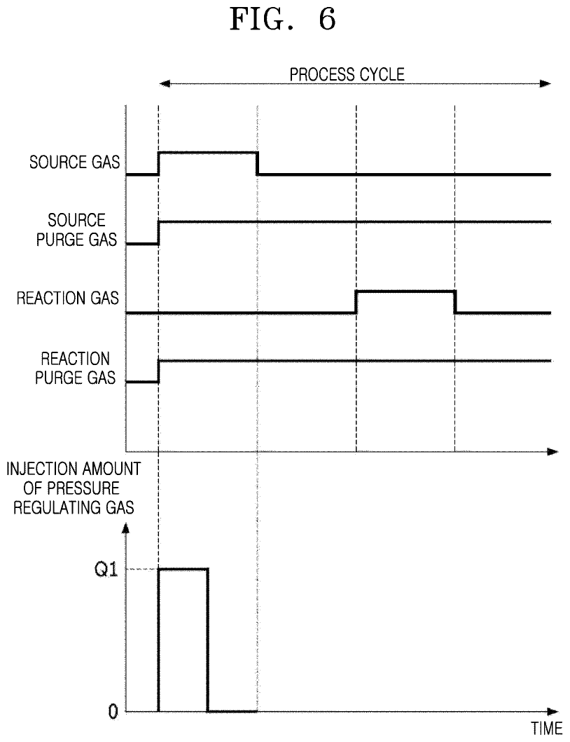

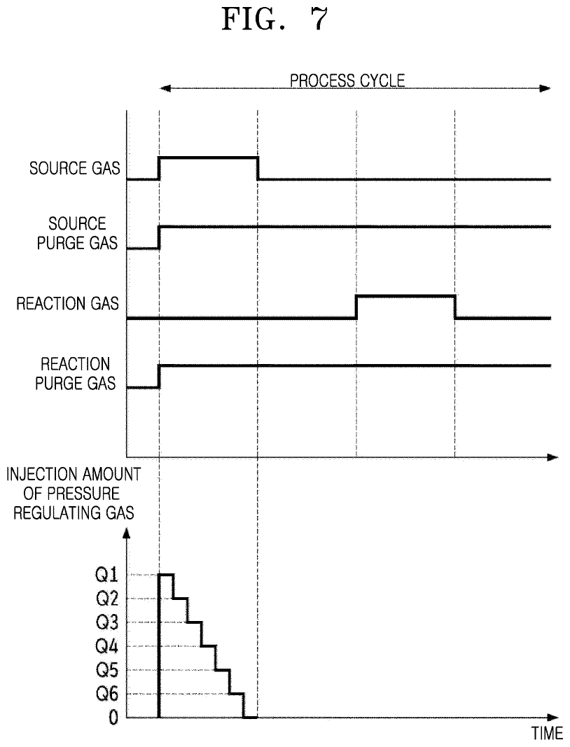

FIG. 5 is a diagram for describing the division of the pressure regulating section into a plurality of sub-sections, FIG. 6 is a diagram for describing that the pressure regulating gas is not injected in the last sub-section among the plurality of sub-sections, and FIG. 7 is a diagram for describing that the amount of the pressure regulating gas decreases as the plurality of sub-sections proceed.

Referring to FIGS. 5 to 7, the processor 500 may divide the pressure regulating section into the plurality of sub-sections and allow a preset amount of the pressure regulating gas to be injected into the exhaust line 300 for each sub-section.

The pressure regulating section may be divided into two sub-sections. For example, the sub-sections may include a first sub-section and a second sub-section. Here, the second sub-section represents a section that proceeds after the first sub-section.

FIG. 5 illustrates that an amount Q1 of the pressure regulating gas is injected in the first sub-section, while an amount Q2, which is less than Q1, of the pressure regulating gas is injected in the second sub-section. The pressure regulating gas may be injected for a second period of time in the first sub-section and for a third period of time in the second sub-section. Here, the sum of the second period of time and the third period of time may correspond to the above-described first period of time, which is a source gas supply time. The second period of time may be greater than or equal to the third period of time. For example, the second period of time may be greater than or equal to the third period of time within a range of about 90% or less of the first period of time.

The injection amount of the pressure regulating gas, Q2, may be less than Q1. For example, Q2 may be less than Q1 within a range of 60% or less of Q1, thereby buffering abrupt changes in the internal pressure of the process chamber 100 and the flow rate of the residual gas.

During the source gas supply time, the pressure regulating gas is injected into the exhaust line 300, and the pressure regulating section corresponding to the source gas supply time is divided into a plurality of sub-sections, thereby allowing the injection amount of the pressure regulating gas to be controlled. Accordingly, at the beginning of the operation in which the source gas is purged after the operation in which the source gas is injected, abrupt changes in the internal pressure and internal flow rate of the process chamber 100 may be prevented, thereby preventing variations in the uniformity characteristics of components disposed inside the process chamber 100 and/or a deposited material deposited on the substrate W.

Referring to FIGS. 6 and 7, the processor 500 may allow the amount of the pressure regulating gas injected into the exhaust line 300 to decrease as the plurality of sub-sections proceed. In particular, the processor 500 may prevent the pressure regulating gas from being injected into the exhaust line 300 in the last sub-section among the plurality of sub-sections.

Referring to FIG. 6, the pressure regulating section may be divided into two sub-sections. The two sub-sections may include a first sub-section and a second sub-section. The second sub-section may be a section that proceeds after the first sub-section.

An amount Q1 of the pressure regulating gas may be injected in the first sub-section, while no pressure regulating gas may be injected in the second sub-section. At this time, the pressure regulating gas may be injected in the first sub-section for a second period of time, while no pressure regulating gas may be injected in the second sub-section for a third period of time.

The sum of the second period of time and the third period of time may correspond to the above-described first period of time, which is the source gas supply time. In addition, the second period of time may be greater than or equal to the third period of time. For example, the second period of time may be greater than or equal to the third period of time within a range of about 90% or less of the first period of time.

That is, when the internal pressure of the process chamber 100 changes abruptly at a time point when the injection of the source gas ends and process by-products are discharged by the source purge gas, turbulence may occur inside the process chamber 100, which may cause the thin film to form with non-uniform thickness. To prevent this, the operation in which the source gas is supplied may include the first sub-section in which the pressure regulating gas is injected and the second sub-section in which no pressure regulating gas is injected. As a result, abrupt changes in the internal pressure and internal flow rate of the process chamber 100 at the beginning of the operation in which the source gas is purged may be prevented.

Referring to FIG. 7, the pressure regulating section may be divided into a plurality of sub-sections. For example, the pressure regulating section may include seven sub-sections. The plurality of sub-sections may include first to seventh sub-sections arranged in chronological order.

An amount Q1 of the pressure regulating gas may be injected in the first sub-section, an amount Q2 of the pressure regulating gas may be injected in the second sub-section, an amount Q3 of the pressure regulating gas may be injected in the third sub-section, an amount Q4 of the pressure regulating gas may be injected in the fourth sub-section, an amount Q5 of the pressure regulating gas may be injected in the fifth sub-section, and an amount Q6 of the pressure regulating gas may be injected in the sixth sub-section. Meanwhile, no pressure regulating gas may be injected into the seventh sub-section.

For example, when the pressure regulating section includes seven sub-sections, percentages of the pressure regulating gas injected into the exhaust line 300 in the first to seventh sub-sections may be 100%, 83.3%, 66.6%, 50%, 33.3%, 16.6%, and 0%, respectively. Meanwhile, setting a constant reduction ratio for the pressure regulating gas is merely an example, and according to some embodiments of the present disclosure, the percentages of the pressure regulating gas injected into the exhaust line 300 in the plurality of sub-sections may be determined in various ways.

In addition, the pressure regulating gas may be injected for second to seventh periods of time in the first to sixth sub-sections, while no pressure regulating gas may be injected during an eighth period of time in the seventh sub-section.

Here, the sum of the second to eighth periods of time may correspond to the above-described first period of time, which is the source gas supply time. Further, the second to seventh periods of time may be the same or different from each other. For example, to induce uniform adsorption of the source gas on both central and edge regions of the substrate W, or to induce uniform adsorption of the source gas on the substrate W located at a relatively greater distance from the gas injector 200, the injection amount and supply time of the pressure regulating gas may be determined to be proportional. In this case, the time may gradually decrease from the second period of time to the seventh period of time. In addition, the sum of the second to seventh periods of time may be greater than or equal to the eighth period of time within a range of about 90% or less of the first period of time.

As the plurality of sub-sections proceed, the amount of the pressure regulating gas injected into the exhaust line 300 gradually decreases, thereby preventing turbulence and enabling the thin film to form with uniform thickness.

As described above, as the plurality of sub-sections proceed, the amount of the pressure regulating gas injected into the exhaust line 300 may be reduced. As the internal pressure of the process chamber 100 gradually decreases, the occurrence of turbulence may be prevented. In addition, as the internal pressure of the process chamber 100 gradually decreases, only the source purge gas may be supplied to the process chamber 100 at a time point when the injection of the source gas ends, thereby allowing the discharge of process by-products to be easily performed.

In the above, the section in which the source gas is injected onto the substrate W has been described as the pressure regulating section, but according to some embodiments of the present disclosure, the section in which the reaction gas is injected onto the substrate W may also be the pressure regulating section. For example, when the reaction gas is a gas containing at least one metal element selected from tin (Sn), nickel (Ni), copper (Cu), titanium (Ti), tungsten (W), gold (Au), silver (Ag), iron (Fe), magnesium (Mg), zirconium (Zr), and platinum (Pt), the processor 500 may control the auxiliary valve 410 and the gas regulator 420 to inject the pressure regulating gas into the exhaust line 300 during the section in which the reaction gas is injected.

In a substrate processing apparatus according to an embodiment of the present disclosure as described above, an internal pressure of a process chamber can be increased by injecting a pressure regulating gas into an exhaust line while injecting a process gas into the process chamber, thereby providing uniform contact opportunities with the process gas for each of a plurality of substrates accommodated in the process chamber.

While the exemplary embodiments of the present disclosure have been described with reference to the accompanying drawings, it should be understood by those skilled in the art that various modifications may be made without departing from the scope of the present disclosure and without changing essential features thereof. Therefore, it should be understood that the above-described embodiments are not restrictive but illustrative in all aspects.

What is claimed is:

1. A substrate processing apparatus comprising:
a process chamber configured to provide a processing space for processing a substrate;
a gas injector configured to inject a process gas onto the substrate;
an exhaust line configured to provide a gas transfer path for discharging process by-products remaining in the process chamber;
an auxiliary line connected to the exhaust line and configured to provide a gas transfer path for injecting a pressure regulating gas into the exhaust line; and
a processor configured to regulate injection of the pressure regulating gas,
wherein the processor allows the pressure regulating gas to be injected into the exhaust line during a pressure regulating section of a process cycle for the substrate.

2. The substrate processing apparatus of claim 1, wherein the pressure regulating section includes a section in which a source gas is injected onto the substrate.

3. The substrate processing apparatus of claim 2, wherein the source gas is a gas containing at least one metal element selected from tin (Sn), nickel (Ni), copper (Cu), titanium (Ti), tungsten (W), gold (Au), silver (Ag), iron (Fe), magnesium (Mg), zirconium (Zr), and platinum (Pt), or a gas containing at least one selected from trimethylaluminum (TMA), diethylene glycol (DEG), titanium chloride (TiCl), tetrakis-dimethylamino tin (TDMASn), methylcyclopentadienyl nickel (MeCpNi), ethylcyclopentadienyl nickel (EtCpNi), and diethyl zinc (DEZ).

4. The substrate processing apparatus of claim 1, wherein the pressure regulating gas includes at least one of nitrogen (N₂) or argon (Ar).

5. The substrate processing apparatus of claim 1, wherein the processor allows a preset amount of the pressure regulating gas to be injected into the exhaust line for each pressure regulating section of a plurality of process cycles for the substrate.

6. The substrate processing apparatus of claim 1, wherein the processor divides the pressure regulating section into a plurality of sub-sections and allows a preset amount of the pressure regulating gas to be injected into the exhaust line for each sub-section.

7. The substrate processing apparatus of claim 6, wherein the processor allows the amount of the pressure regulating gas injected into the exhaust line to decrease as the plurality of sub-sections proceed.

8. The substrate processing apparatus of claim 7, wherein the processor prevents the pressure regulating gas from being injected into the exhaust line in a last sub-section among the plurality of sub-sections.

9. The substrate processing apparatus of claim 1, further comprising a gas regulator provided in the auxiliary line and configured to regulate a transfer amount of the pressure regulating gas transferred through the auxiliary line.

10. The substrate processing apparatus of claim 1, further comprising an auxiliary valve provided in the auxiliary line and configured to open or close the auxiliary line.

11. The substrate processing apparatus of claim 1, wherein the substrate is used as a material for a solar cell using a perovskite material.

12. The substrate processing apparatus of claim 1, wherein the process chamber includes:
a substrate inlet/outlet formed on one side of the process chamber; and
a shutter configured to open or close the substrate inlet/outlet.

13. The substrate processing apparatus of claim 12, wherein the process chamber further includes an exhaust port connected to the exhaust line, and the exhaust port is disposed on a side of the process chamber opposite to a side of the process chamber on which the gas injector is disposed.

14. The substrate processing apparatus of claim 1, further comprising a substrate support part configured to support the substrate while the substrate is brought into or taken out of the process chamber.

15. The substrate processing apparatus of claim 14, the substrate support part includes:
a main support part provided in the form of a panel; and
plurality of sub-support parts arranged in a longitudinal direction of the main support part.
